(19) United States
(12) Patent Application Publication
(10) Pub. No.: US 2011/0182317 A1
(43) Pub. Date: Jul. 28, 2011

(54) SURFACE EMITTING SEMICONDUCTOR LASER HAVING A PLURALITY OF ACTIVE ZONES

(75) Inventors: Peter Brick, Regensburg (DE); Martin Müller, Regenstauf (DE)

(73) Assignee: OSRAM OPTO SEMICONDUCTORS GMBH, Regensburg (DE)

(21) Appl. No.: 12/989,094

(22) PCT Filed: Jun. 25, 2009
(86) PCT No.: PCT/DE09/00881

§ 371 Date: Oct. 22, 2010

(30) Foreign Application Priority Data
Jun. 30, 2008 (DE) 10 2008 030 818.8

(51) Int. Cl. H01S 5/18

(52) U.S. Cl. 372/50.124

(57) ABSTRACT

A surface emitting semiconductor laser includes a semiconductor body having at least two active zones that emit laser radiation and are connected to one another by a tunnel junction; an external resonator mirror arranged outside the semiconductor body and forming a laser resonator; and at least one polarization-selective element arranged in the laser resonator.

### RELATED APPLICATIONS

This is a §371 of International Application No. PCT/DE2009/000881, with an international filing date of Jun. 25, 2009 (WO 2010/000231 A1, published Jan. 7, 2010), which is based on German Patent Application No. 10 2008 030 818.8, filed Jun. 30, 2008, the subject matter of which is incorporated by reference.

### TECHNICAL FIELD

This disclosure relates to a surface emitting semiconductor laser having a plurality of active zones.

### BACKGROUND

DE 102006010728 A1 discloses a surface emitting semiconductor laser comprising a semiconductor body having a plurality of active regions suitable for generating radiation and arranged in a manner spaced apart from one another, wherein, between two active regions, a tunnel junction is monolithically integrated in the semiconductor body, and the two active regions are electrically conductively connected by the tunnel junction. It is thus possible to obtain a high radiation power with a compact semiconductor body. The semiconductor laser has an external resonator mirror, wherein, in particular, a frequency conversion element for the frequency conversion of the radiation emitted by the semiconductor laser can be arranged in the external resonator formed between the semiconductor body and the external resonator mirror. The beam shaping in the case of a surface emitting semiconductor laser of this type is typically effected by virtue of the fact that the external resonator mirror is curved.

The laser radiation emitted by surface emitting semiconductor lasers generally does not have a defined polarization direction. For many applications it is desirable to be able to use a compact semiconductor laser which also has a defined polarization alongside a high output power and good beam shape.

It could therefore be helpful to provide a surface emitting semiconductor laser distinguished both by a high output power and by a defined polarization direction of the emitted laser radiation.

### SUMMARY

We provide a surface emitting semiconductor laser including a semiconductor body having at least two active zones that emit laser radiation and connected to one another by a tunnel junction, an external resonator mirror arranged outside the semiconductor body and forming a laser resonator, and at least one polarization-selective element arranged in the laser resonator.

### BRIEF DESCRIPTION OF THE DRAWINGS

FIG. 1 shows a schematically illustrated cross section of a surface emitting semiconductor laser in accordance with a first example.

FIG. 2 shows a schematically illustrated cross section of a surface emitting semiconductor laser in accordance with a second example.

FIG. 3 shows a schematically illustrated cross section of a surface emitting semiconductor laser in accordance with a third example.

FIG. 4 shows a schematically illustrated cross section of a surface emitting semiconductor laser in accordance with a fourth example.

FIG. 5 shows a schematically illustrated cross section of a surface emitting semiconductor laser in accordance with a fifth example.

### DETAILED DESCRIPTION

A surface emitting semiconductor laser may have a semiconductor body which contains at least two active zones for the emission of laser radiation and is connected to one another by a tunnel junction. Furthermore, the surface emitting semiconductor laser may have an external resonator mirror arranged outside the semiconductor body and serving for forming a laser resonator. The external resonator mirror preferably forms, together with a resonator mirror contained in the semiconductor body, for example, a Bragg mirror, the laser resonator of the surface emitting semiconductor laser, wherein at least one polarization-selective element is arranged in the laser resonator.

What is advantageously achieved by the integration of a polarization-selective element into the laser resonator of the surface emitting semiconductor laser is that the surface emitting semiconductor laser emits laser radiation having a defined polarization such that further polarization-selective elements arranged outside the laser resonator can be dispensed. The surface emitting semiconductor laser is therefore distinguished first by a high output power obtained by the plurality of active zones and, second, by a defined polarization of the emitted laser radiation.

The polarization-selective element is preferably a polarization-selective grating. The polarization-selective grating is preferably a dielectric transmission grating. A dielectric transmission grating is distinguished, in particular, by a high radiation resistance. This advantageously enables a transmission grating of this type to be integrated into the laser resonator of the surface emitting semiconductor laser.

Dielectric transmission gratings are known per se, for example, from T. Clausnitzer, T. Kämpfe, E.-B. Kley, A. Tünnermann, A. V. Tishchenko, O. Parriaux, “Hocheffiziente dielektrische Transmissionsgitter-eine anschauliche Untersuchung des Beugungsverhaltens” [“High-efficiency dielectric transmission gratings—an illustrative examination of the diffraction behavior”], Photonik 1/2007, pp. 48-51.

Preferably, the polarization-selective element, in particular a polarization-selective transmission grating, is arranged on a radiation exit area of the semiconductor body. Arranging the polarization-selective element on a radiation exit area of the semiconductor body advantageously reduces the mounting and alignment outlay during the production of the surface emitting semiconductor laser and simultaneously results in a compact construction.

The radiation exit area of the semiconductor body on which the polarization-selective element is arranged can be, for example, a substrate of the surface emitting semiconductor laser. In this case, the semiconductor body is preferably embodied as a so-called “bottom emitter,” that is to say that the emitted laser radiation emerges from the semiconductor body through the substrate. The substrate is, in particular, the growth substrate on which the semiconductor layers of the semiconductor body, in particular the at least two active zones and the tunnel junction arranged therebetween, are grown epitaxially.

Alternatively, the semiconductor body has a current spreading layer wherein the surface of the current spreading layer functions as a radiation exit area. In this case, the polarization-selective element is preferably applied to the surface of the current spreading layer. A growth substrate on which the semiconductor layers of the semiconductor body have been grown preferably epitaxially is advantageously removed from the semiconductor body, that is to say that the semiconductor body has no growth substrate. In this case, the semiconductor body can be mounted onto a carrier at a side lying opposite the current spreading layer.

The current spreading layer, on which the polarization-selective element is arranged, is preferably an n-doped layer. In this case, therefore, the laser radiation is coupled out through the n-doped current spreading layer. The semiconductor body is preferably mounted onto a carrier at a p-doped region lying opposite the current spreading layer.

That surface of the semiconductor body which is provided with the polarization-selective element, for example, the substrate or the current spreading layer of the semiconductor body, is preferably shaped as a lens. In this configuration, that surface of the semiconductor body through which the laser radiation emitted by the active layers emerges from the semiconductor body is preferably processed by an etching method to produce a curvature corresponding to the desired lens shape at the radiation exit area of the semiconductor body. In particular, the surface of the semiconductor body can be processed in such a way that it has a convexly curved surface.

In this way, a beam-shaping element is advantageously integrated into the semiconductor body of the surface emitting semiconductor laser. In this case, the surface emitting semiconductor laser is distinguished not only by a defined polarization direction of the emitted laser radiation, but also by good beam shaping. In particular, the integration of a lens into the semiconductor body of the surface emitting semiconductor laser allows a very compact construction since external optical elements for beam shaping can be dispensed with. A lens integrated into the semiconductor body of the surface emitting semiconductor laser furthermore has the advantage that it is possible to obtain a small beam cross section in the external resonator even when a planar external resonator mirror is used.

In a further advantageous configuration, the polarization-selective element is arranged on a surface of the external resonator mirror. In particular, a polarization-selective grating can be applied to the surface of the external resonator mirror. By virtue of the fact that the polarization-selective element is applied to a surface of the external resonator mirror, it is advantageously not necessary for the polarization-selective element additionally to be mounted and aligned in the surface emitting semiconductor laser. In this way, the production outlay is reduced and a compact construction of the surface emitting semiconductor laser is obtained.

In a further advantageous configuration, the laser resonator has a folding mirror and the polarization-selective element, in particular a polarization-selective grating, is arranged on a surface of the folding mirror. A folded laser resonator is formed with the folding mirror arranged between the semiconductor body and the external resonator mirror.

In particular, the folding mirror can be a 45° mirror. In this case, the laser radiation emitted by the at least two active zones of the surface emitting semiconductor laser impinges on the folding mirror at an angle of incidence of 45° and is reflected from the folding mirror at an angle of reflection of 45°. In this case, therefore, the folding mirror brings about a deflection of the emitted laser radiation by 90°. Alternatively, however, the folding mirror can also be arranged at different angles with respect to the laser radiation emitted by the semiconductor body.

The polarization-selective element applied on the folding mirror is preferably a polarization-selective reflective coating. The polarization-selective reflective coating preferably has a layer sequence composed of dielectric layers. The polarization-selective reflective coating preferably has, at the angle of incidence of the laser radiation, a reflectivity Rₚ for p-polarized light and a reflectivity Rₛ for s-polarized light, where Rₚ≠Rₛ.

Rₚ/Rₛ<0.95 preferably holds true. In this case, therefore, the reflectivity for p-polarized light is lower than that for s-polarized light. What is thereby achieved is that the amplification for p-polarized light in the laser resonator is so low that the laser builds up oscillations only for the radiation in the s-polarized state. The surface emitting semiconductor laser therefore emits s-polarized light in this case.

Alternatively, the reflectivity for s-polarized light could also be lower than that for p-polarized light, where Rₛ /Rₚ<0.95 preferably holds true. The surface emitting semiconductor laser emits p-polarized light in this case.

A suitable reflective coating, in particular a dielectric layer system having a desired ratio of the reflectivity for p-polarization to the reflectivity for s-polarization for a predefined angle of incidence, can be determined on the basis of simulation calculations taking account of the angle of incidence and the wavelength.

Furthermore, it is advantageous if the external resonator mirror has a reflection maximum at a first wavelength λ₁ and the folding mirror has a reflection maximum at a second wavelength λ₂, wherein the wavelength of the emitted laser radiation λ_{L} lies between λ₁ and λ₂. In this case, the reflection maxima of the resonator mirror and of the folding mirror are at least slightly shifted relative to one another. In this case, the reflection curve of the external resonator mirror and that of the folding mirror advantageously overlap one another. In this case, the laser can build up oscillations only at a wavelength between λ₁ and λ₂ at which both the external resonator mirror and the folding mirror have a sufficiently high reflectivity.

As a result of the at least slight shift in the reflection maxima of the external resonator mirror and of the folding mirror with respect to one another, a wavelength selection is obtained. An additional wavelength-selective element in the laser resonator can therefore advantageously be dispensed with. This contributes to the fact that the production and mounting outlay is reduced and a compact construction of the surface emitting semiconductor laser is obtained.

A frequency conversion element may also be arranged in the external resonator of the surface emitting semiconductor laser.

The frequency conversion element is an optical element suitable for multiplying, in particular doubling, the frequency of the emitted laser radiation. The frequency conversion element is preferably a nonlinear optical crystal.

In this way, by way of example, with a semiconductor material that generates radiation in the near infrared spectral range, it is possible to generate laser radiation in the visible range of the spectrum, in particular blue or green laser radiation.

In case of the arrangement of a frequency conversion element in the laser resonator, it is advantageous if the radiation exit area of the semiconductor body, for example, the substrate or a current spreading layer is shaped as a lens. In this case, it is possible to obtain a small beam cross section of the laser radiation in the region of the frequency conversion element, in particular even when a planar mirror is used as external mirror.

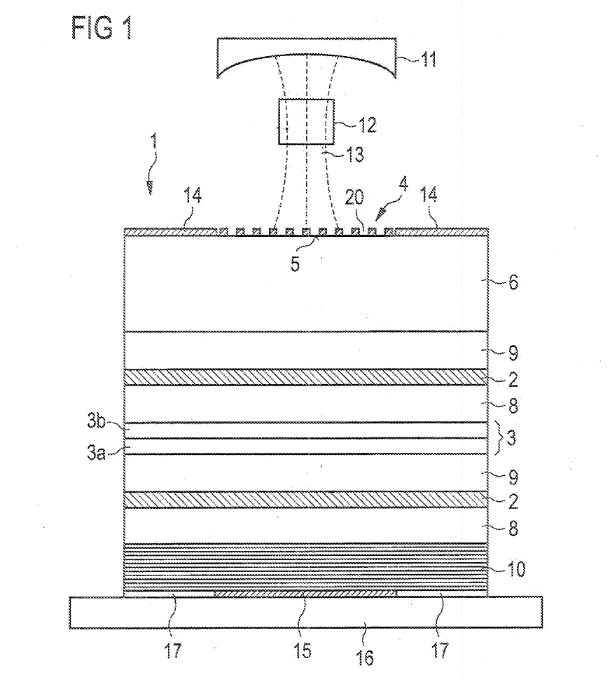

Our lasers are explained in greater detail below on the basis of examples in association with FIGS. 1 to 5.

Identical or identically acting constituent parts are in each case provided with the same reference symbols. The illustrated constituent parts and also the size relationships of the constituent parts among one another should not be regarded as true to scale.

FIG. 1 illustrates an example of a surface emitting semiconductor laser having at least two active zones 2 connected to one another by a tunnel junction 3. The two active zones 2 are monolithically integrated into the semiconductor body 1 of the surface emitting semiconductor laser. The two active zones 2 are contained in a semiconductor layer sequence preferably produced epitaxially and grown on a growth substrate 6, and are spaced apart from one another in a vertical direction within the semiconductor layer sequence.

The radiation-emitting active zones 2 preferably each have a single or multiple quantum well structure. “Quantum well structure” encompasses any structure in which charge carriers experience a quantization of their energy states as a result of confinement. In particular, the designation quantum well structure does not include any indication about the dimensionality of the quantization. It therefore encompasses, inter alia, quantum wells, quantum wires and quantum dots and any combination of these structures.

The semiconductor body 1 of the surface emitting semiconductor laser is preferably based on a III-V compound semiconductor, in particular on an arsenide compound semiconductor. “Based on an arsenide compound semiconductor” means that the active epitaxial layer sequence or at least one layer thereof comprises an arsenide compound semiconductor material, preferably AlₙGaₘIn₁₋ₙ₋ₘAs, where 0≦n≦1, 0 ≦m≦1 and n+m 1. In this case, this material need not necessarily have a mathematically exact composition according to the above formula. Rather, it can comprise one or more dopants and additional constituents which substantially do not change the characteristic physical properties of the AlₙGaₘIn₁₋ₙ₋ₘAs material. For the sake of simplicity, however, the above formula only includes the essential constituents of the crystal lattice (Al, Ga, In, As), even if these can be replaced in part by small amounts of further substances.

Alternatively, the active zones 2 can also comprise a nitride compound semiconductor material, preferably AlₙGaₘIn₁₋ₙ₋ₘN, an antimonide compound semiconductor material, preferably AlₙGaₘIn₁₋ₙ₋ₘSb, or a phosphide compound semiconductor material, preferably AlₙGaₘIn_{1-n-N}P, where 0≦n≦1, 0≦m≦1 and n+m≦1.

The active zones 2 are in each case arranged between semiconductor regions 8, 9 having opposite conduction types. By way of example, the active zones 2 are in each case arranged between a p-doped semiconductor region 8 and an n-doped semiconductor region 9. The active zones 2 are connected in series with one another by the tunnel junction 3. The tunnel junction 3 preferably contains at least two tunnel contact layers 3a, 3b, which have different electrical conduction types and are preferably highly doped. In this case, the tunnel contact layers 3a, 3b preferably each have the same conduction type as the semiconductor regions 8, 9 adjoining them. By way of example, the tunnel contact layer 3a adjoining the n-doped semiconductor region 9 is an n-doped layer, preferably having a high dopant concentration (n⁺). The further tunnel contact layer 3b adjoining the p-doped semiconductor region 8 is preferably a p-doped layer, in particular having a high dopant concentration (p⁺).

The two tunnel contact layers 3a, 3b can, as illustrated in FIG. 1, directly adjoin one another. Alternatively, however, it is also possible for the tunnel contact 3 to contain one or more further layers, for example, an undoped layer arranged between the two highly doped layers 3a, 3b.

To form a laser resonator for the laser radiation 13 emitted by the two active layers 2, the surface emitting semiconductor laser contains a first resonator mirror 10, which is preferably integrated into the semiconductor body 1, and a second resonator mirror 11, which, by way of example, is an external resonator mirror arranged outside the semiconductor body 1.

The first resonator mirror 10 integrated into the semiconductor body 1 is preferably a Bragg mirror which, to obtain a high reflectivity, is formed by a multiplicity of layer pairs composed of layers having different refractive indices. By way of example, the Bragg mirror can have a multiplicity of alternating layers of Al₁₋ₓGaₓAs where 0≦x≦1 which differ from one another in terms of their aluminum content. The Bragg mirror preferably contains at least ten layer pairs.

For the purpose of making electrical contact, the surface emitting semiconductor laser contains a first electrical contact 14 and a second electrical contact 15 which are embodied as metal contacts, for example. The first electrical contact 14 is, for example, an n-type contact and applied to a rear side of the substrate 6 remote from the active layers 2. The second electrical contact 15 is, for example, a p-type contact and applied to that surface of the semiconductor body 1 which lies opposite the substrate 6.

In the example illustrated in FIG. 1, the surface emitting semiconductor laser is embodied as a so-called “bottom emitter,” that is to say that the laser radiation 13 emerges from the semiconductor body 1 through a rear-side surface 5 of the substrate 6. To avoid radiation absorption, the first electrical contact 14 is not applied to the entire rear side of the substrate 6, but rather preferably only covers the edge regions of the rear side of the substrate 6. In particular, the first electrical contact 14 can be embodied as a ring contact which surrounds in a ring-shaped fashion a region of the rear side of the substrate 6 that serves as a radiation exit area 5. Furthermore, it is advantageous if the second electrical contact 15, which can be a p-type contact, in particular, is only applied to a central partial region of that surface of the semiconductor body 1 which lies opposite the substrate 6. In this way, the current flow through the semiconductor body 1 is concentrated onto a central region in which the laser radiation is coupled out at the rear side of the substrate 6.

The semiconductor body 1 at the surface lying opposite the substrate 6 can be arranged on a carrier 16, for example, a printed circuit board or a heat sink. The regions of the surface of the semiconductor body 1 which lie outside the central p-type contact can, if appropriate, be insulated from the carrier 16 by an electrically insulating layer 17.

That surface of the substrate 6, which serves as a radiation exit area 5, is provided with a polarization-selective element 4. The polarization-selective element 4 is a polarization-selective transmission grating 20. The polarization-selective grating 20 can be produced, for example, by application of a layer, in particular of a dielectric layer, and subsequent patterning by a patterning method such as photolithography, for example.

The orientation and the grating constant of the polarization-selective grating 20 are set in a manner dependent on the wavelength emitted by the active zones in such a way that the transmission of the grating for one of the polarization directions of the emitted laser light 13, for example, the s-polarization, is greater than the transmission for the polarization component perpendicular thereto, for example, the p-polarization.

What is achieved in this way is that only a specific polarization direction, for example, the s-polarization, is amplified in the laser resonator formed from the first resonator mirror 10 and the external resonator mirror 11. For the other polarization component, for example, the p-polarization, the transmission losses in the polarization-selective grating 20 are preferably so high that the laser threshold is not reached for this polarization component and, consequently, the surface emitting semiconductor laser can only build up oscillations with the other polarization component, for example, the s-polarization.

As a result of the monolithic integration of at least two active zones 2 and the arrangement of a polarization-selective element 4 in the laser resonator of the surface emitting semiconductor laser, therefore, laser radiation having a high output power and a polarization set in a defined fashion is advantageously generated. By virtue of the fact that the polarization-selective element 4 is applied to the semiconductor body 1, no additional optical components have to be introduced into the external resonator of the surface emitting semiconductor laser for this purpose, with the result that the production outlay and mounting outlay are comparatively low.

Furthermore, a frequency conversion element 12 can be arranged in the external resonator. The frequency conversion element 12 can be, in particular, an optically nonlinear crystal.

The frequency conversion is, in particular, a frequency multiplication, for example, a frequency doubling. In particular, the active zones 2 of the surface emitting semiconductor laser can be suitable for emitting infrared radiation, wherein the infrared radiation is converted into visible light, preferably into green or blue visible light, by the frequency conversion element 12 in the laser resonator.

The frequency conversion element 12 is preferably arranged in the external resonator in such a way that the laser radiation has a beam waist within the frequency conversion element 12. The efficiency of the frequency conversion is improved by a small beam cross section at the location of the frequency conversion element 12.

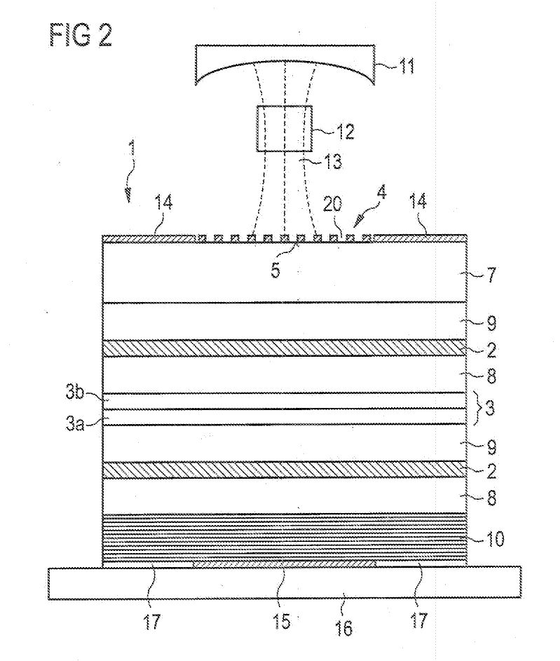

The example illustrated in FIG. 2 differs from the example described above in that the polarization-selective element 4 is not at a surface of a substrate of the semiconductor body 1, but rather at a surface of a current spreading layer 7 which functions as a radiation exit area 5. The production of a polarization-selective element 4 in the form of a polarization-selective transmission grating 20 can be effected, as in the example described above, by application of a preferably dielectric layer and subsequent patterning.

In this example, the growth substrate originally used for growing the semiconductor layer sequence of the semiconductor body 1 has been stripped away from the semiconductor body 1 and is therefore no longer contained in the semiconductor body 1. The semiconductor body 1 is therefore a so-called “thin-film semiconductor chip.” The growth substrate originally used may have been stripped away from the current spreading layer 7, for example. The semiconductor body 1 is preferably mounted onto a carrier 16 at a side lying opposite the original growth substrate.

The original growth substrate need not necessarily be stripped away completely from the semiconductor body 1, as illustrated in FIG. 2. It is also possible, for example, for the original growth substrate to be only partly thinned, in which case the polarization-selective element 4 is then applied to the surface of the thinned growth substrate in a manner similar to that in the example illustrated in FIG. 1. In this case, the electrically conductive growth substrate, which is preferably n-conducting, can itself serve as a current spreading layer.

For the rest, the example illustrated in FIG. 2 corresponds with regard to its functioning and its advantageous configurations to the example described above and will therefore not be explained more specifically in detail.

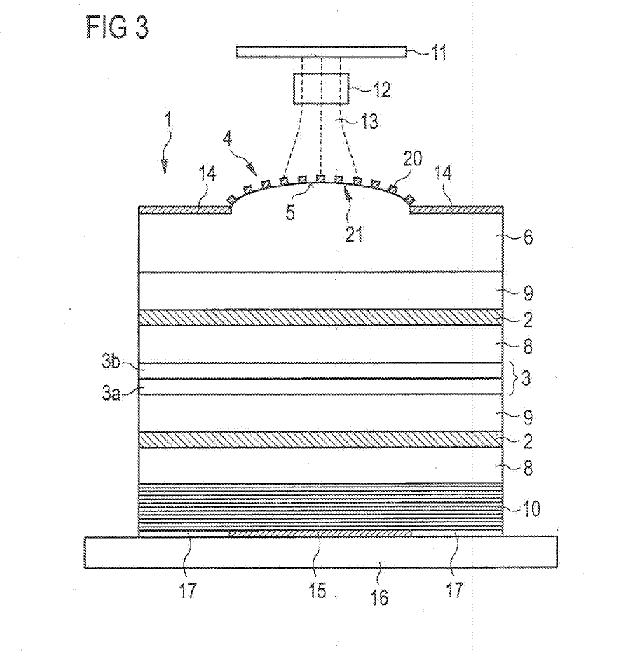

FIG. 3 shows a further modification of the example illustrated in FIG. 1. It differs from the example illustrated in FIG. 1 in that the surface 5 of the substrate 6, to which surface the polarization-selective element 4 is applied, is shaped as a lens 21. The lens 21 can be formed at the rear-side surface 5 of the substrate 6 by an etching process, in particular. By virtue of the fact that the lens 21 is integrated into the semiconductor body 1 in this way, both a beam shaping by the lens 21 and a polarization selection by the polarization-selective grating 20 are effected when the laser radiation 13 emerges from the semiconductor body 1.

The lens 21 formed in the semiconductor body 1 has the advantage, in particular, that the second resonator mirror 11, arranged outside the semiconductor body 1, can be a planar mirror. A planar external resonator mirror 11 can be produced comparatively simply and cost-effectively in comparison with the conventionally used curved external resonator mirrors. Despite the use of a planar external resonator mirror 11, the laser radiation 13 has a small beam cross section in the external resonator between the semiconductor body 1 and the external resonator mirror 11. This is advantageous particularly when a frequency conversion element 12 is arranged in the external resonator. The frequency conversion element 12 can be, in particular, an optically nonlinear crystal.

Otherwise, the example illustrated in FIG. 3 corresponds with regard to its construction and its advantageous configurations to the example illustrated in FIG. 1 and will therefore not be explained again more specifically in detail.

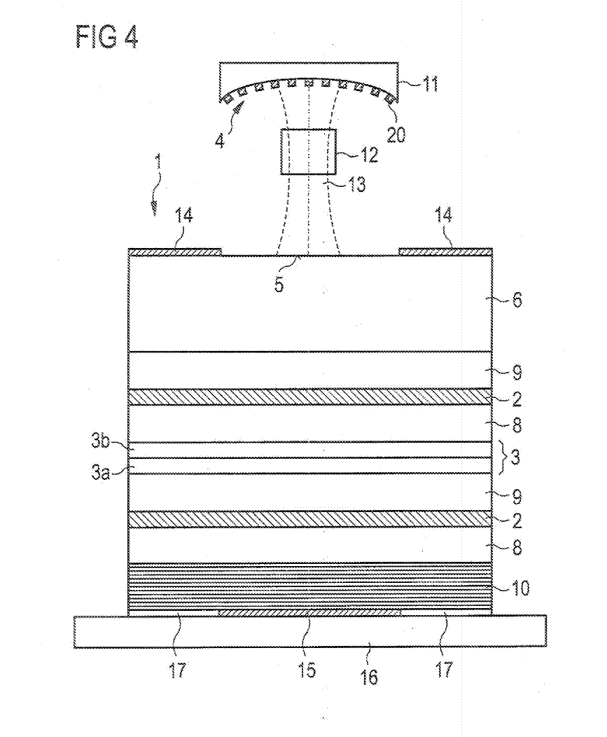

FIG. 4 shows a further modification of the example illustrated in FIG. 1. In this example, the polarization-selective element 4 in the form of a polarization-selective grating 20 is not applied to the radiation exit area 5 of the substrate 6, but rather to that surface of the external resonator mirror 11 which faces the semiconductor body 1.

In this configuration, too, the polarization-selective element 4 is applied to an optical component of the surface emitting semiconductor laser which is already present per se, with the result that it is not necessary to arrange and align an additional optical element in the surface emitting semiconductor laser. The polarization-selective grating 20 can be produced onto the external resonator mirror 11, as in the examples described above, by application of a preferably dielectric layer and a subsequent patterning process.

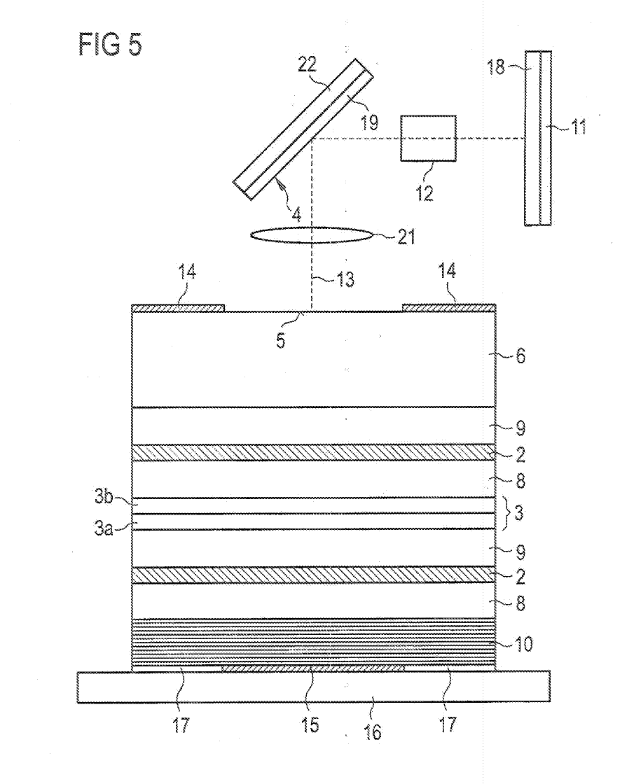

The example illustrated in FIG. 5 differs from the examples described above in that the laser resonator formed by the first resonator mirror 10 and the external resonator mirror 11 has a folding mirror 22.

The folding mirror 22 is a 45° mirror, on which the laser radiation 13 emerging from the semiconductor body 1 impinges at an angle of 45° and is reflected at an angle of reflection of 45° to the external resonator mirror 11. The laser radiation 13 is therefore deflected by 90° by the folding mirror 22. In this example, the polarization-selective element 4 is applied to the folding mirror 22.

In contrast to the examples described above, the polarization-selective element 4 is not a polarization-selective grating, but rather a polarization-selective reflective coating 19. The polarization-selective reflective coating 19 is preferably a layer sequence composed of dielectric layers. The polarization-selective reflective coating 19 has reflectivities of different magnitudes for s-polarized radiation and p-polarized radiation at the angle of incidence of the laser radiation 13, which is 45° in this example. By virtue of the fact that the reflectivity of the folding mirror for one polarization component, for example, s-polarized radiation, is greater than that for the other polarization component, for example, p-polarized radiation, what can be achieved is that the laser builds up oscillations only for laser radiation with the polarization component for which the folding mirror 22 has the higher reflectivity.

Preferably, the folding mirror has a reflectivity Rₚ for p-polarized radiation and a reflectivity Rₛ for s-polarized radiation, where Rₚ/Rₛ<0.95 holds true. In this case, therefore, the surface emitting semiconductor laser would advantageously build up oscillations only for laser radiation having s-polarization.

Preferably, the external resonator mirror 11 is provided with a reflective coating 18 and the folding mirror 22 is provided with a reflective coating 19, wherein the reflectivity of the reflective coatings 18, 19 is chosen such that the external resonator mirror 11 has a reflection maximum at a first wavelength λ₁ and the folding mirror 22 has a reflection maximum at a second wavelength λ₂.

The first wavelength λ₁ and the second wavelength λ₂ are preferably slightly shifted relative to one another, such that only for a wavelength between λ₁ and λ₂ at which the two reflection curves overlap one another is the total reflectivity of the laser resonator sufficiently high that the surface emitting semiconductor laser can build up oscillations at this wavelength. In this case, therefore, the wavelength λ_{L} of the emitted laser radiation lies between λ₁ and λ₂. By virtue of the reflection maxima of the external resonator mirror 11 and of the folding mirror 22 that are at least slightly shifted relative to one another, a wavelength selection is therefore obtained within the laser resonator without additional optical elements having to be inserted into the laser resonator for this purpose.

Furthermore, a lens 21 can be arranged in the laser resonator to focus the laser radiation 13 into a frequency conversion element 12 arranged in the laser resonator. By way of example, the lens 21 is arranged between the semiconductor body 1 and the folding mirror 22, and the frequency conversion element 12 is arranged between the folding mirror 22 and the external resonator mirror 11.

Alternatively, it would also be possible, as in the example illustrated in FIG. 3, for a surface of the semiconductor body 1 to be shaped as a lens, for example, a surface of the substrate 6 or of a current spreading layer which serves as a radiation exit area 5. The mounting and alignment outlay is advantageously reduced in the case of such integration of the lens into the semiconductor body 1.

This disclosure is not restricted by the description on the basis of the examples. Rather, the disclosure encompasses any novel feature and also any combination of features, which in particular includes any combination of features in the appended claims, even if this feature or this combination itself is not explicitly specified in those claims or the examples.

1. A surface emitting semiconductor laser comprising:
a semiconductor body having at least two active zones that emit laser radiation and are connected to one another by a tunnel junction;
an external resonator mirror arranged outside the semiconductor body and forming a laser resonator; and
at least one polarization-selective element arranged in the laser resonator.

2. The surface emitting semiconductor laser as claimed in claim 1,
wherein the polarization-selective element is a polarization-selective grating.

3. The surface emitting semiconductor laser as claimed in claim 1,
wherein the polarization-selective element is arranged on a radiation exit area of the semiconductor body.

4. The surface emitting semiconductor laser as claimed in claim 3,
wherein the semiconductor body has a substrate and the radiation exit area is a surface of the substrate.

5. The surface emitting semiconductor laser as claimed in claim 3,
wherein the semiconductor body has a current spreading layer and the radiation exit area is a surface of the current spreading layer.

6. The surface emitting semiconductor laser as claimed in claim 3,
wherein the radiation exit area is shaped as a lens.

7. The surface emitting semiconductor laser as claimed in claim 1,
wherein the polarization-selective element is arranged on a surface of the external resonator mirror.

8. The surface emitting semiconductor laser as claimed in claim 1,
wherein the laser resonator has a folding mirror and the polarization-selective element is arranged on a surface of the folding mirror.

9. The surface emitting semiconductor laser as claimed in claim 8,
wherein the folding mirror is a 45° mirror.

10. The surface emitting semiconductor laser as claimed in claim 8,
wherein the polarization-selective element is a polarization-selective reflective coating.

11. The surface emitting semiconductor laser as claimed in claim 10,
wherein the polarization-selective reflective coating has a layer sequence composed of dielectric layers.

12. The surface emitting semiconductor laser as claimed in claim 10,
wherein the polarization-selective reflective coating has a reflectivity Rₚ for p-polarized radiation and a reflectivity Rₛ for s-polarized radiation, where Rₚ/R₄<0.95.

13. The surface emitting semiconductor laser as claimed in claim 8,
wherein the external resonator mirror has a reflection maximum at a first wavelength λ₁ and the folding mirror has a reflection maximum at a second wavelength λ₂, and wherein the wavelength λ₁, of the emitted laser radiation lies between λ₁ and λ₂.

14. The surface emitting semiconductor laser as claimed in claim 1,
wherein a frequency conversion element is arranged in the external resonator.

15. The surface emitting semiconductor laser as claimed in claim 14,
wherein the laser radiation has a beam waist in the region of the frequency conversion element.

16. The surface emitting semiconductor laser as claimed in claim 2, wherein the polarization-selective element is arranged on a radiation exit area of the semiconductor body.

17. The surface emitting semiconductor laser as claimed in claim 2, wherein the polarization-selective element is arranged on a surface of the external resonator mirror.

18. The surface emitting semiconductor laser as claimed in claim 9, wherein the polarization-selective element is a polarization-selective reflective coating.

19. The surface emitting semiconductor laser as claimed in claim 11, wherein the polarization-selective reflective coating has a reflectivity Rₚ for p-polarized radiation and a reflectivity Rₛ for s-polarized radiation, where Rₚ/Rₛ<0.95.
